(19) United States
(12) Patent Application Publication
(10) Pub. No.: US 2023/0132530 A1
(43) Pub. Date: May 4, 2023

(54) METHODS OF FORMING SEMICONDUCTOR DEVICES

(71) Applicant: Yangtze Memory Technologies Co., Ltd., Wuhan (CN)

(72) Inventors: LinChun WU, Wuhan (CN); Kun ZHANG, Wuhan (CN); Wenxi ZHOU, Wuhan (CN); ZhiLiang XIA, Wuhan (CN); ZongLiang HUO, Wuhan (CN)

(73) Assignee: Yangtze Memory Technologies Co., Ltd., Wuhan (CN)

(21) Appl. No.: 17/645,794

(22) Filed: Dec. 23, 2021

Related U.S. Application Data
(63) Continuation of application No. PCT/CN2021/127742, filed on Oct. 30, 2021.

(51) Int. Cl. H01L 27/11582; H01L 21/768; H01L 29/66; H01L 25/00

(52) U.S. Cl. CPC H01L 27/11582; H01L 21/76898; H01L 29/66545; H01L 25/50

(57) ABSTRACT

Aspects of the disclosure provide a method for semiconductor device fabrication. The method includes forming a vertical structure in a stack of layers with an end in a first layer by processing on a first side of a first die. The first layer has a better etch selectivity to the stack of layers than a second layer. The method further includes replacing the first layer with the second layer by processing on a second side of the first die that is opposite to the first side.

### TECHNICAL FIELD

The present application describes embodiments generally related to fabrication processes for semiconductor devices.

### BACKGROUND

Semiconductor manufactures developed vertical device technologies, such as three dimensional (3D) NAND flash memory technology, and the like to achieve higher transistor density without requiring smaller transistors. In some examples, a 3D NAND memory device includes an array of vertical memory cell strings. Each vertical memory cell string includes multiple memory cells that are connected in series. Increasing the number of memory cells in the vertical memory cell string can increase data storage density.

### SUMMARY

Aspects of the disclosure provide a method for semiconductor device fabrication. The method includes forming a vertical structure in a stack of layers with an end in a first layer by processing on a first side of a first die. The first layer has a better etch selectivity to the stack of layers than a second layer. The method further includes replacing the first layer with the second layer by processing on a second side of the first die that is opposite to the first side.

In some examples, the first layer includes tungsten and the second layer includes a semiconductor layer, such as a polysilicon layer.

According to an aspect of the disclosure, the vertical structure corresponds to a channel structure, and an initial first stack of layers includes the first layer in a core region. The stack of layers corresponds to an initial second stack of layers. The method then includes forming the initial second stack of layers that comprises insulating layers and sacrificial gate layers stacked alternatingly over the initial first stack of layers.

In some examples, the method includes forming a channel hole in the initial second stack of layers with an end in the first layer, and forming the channel structure in the channel hole. Specifically, in some examples, the channel structure comprises a channel layer that is wrapped in a blocking insulating layer, a charge storage layer, and a tunneling insulating layer. Then, the replacing the first layer with the second layer further includes removing the first layer by the processing on the second side; and removing the blocking insulating layer, the charge storage layer, and the tunneling insulating layer from an end of the channel structure by the processing on the second side.

In some examples, to replace the first layer with the second layer, the method includes forming the second layer in contact with the channel layer at the end of the channel structure. For example, the method can include forming a semiconductor layer in contact with the channel layer at the end of the channel structure by the processing on the second side. Specifically, in an example, the method includes forming a liner portion of the semiconductor layer. The liner portion contacts the channel layer at the end of the channel structure. Then, the method includes performing ion implantation to dope the liner portion, and forming a bulk portion of the semiconductor layer. Further, the method includes forming a pad structure on the second side, the pad structure being conductively connected with the semiconductor layer.

According to another aspect of the disclosure, the vertical structure corresponds to a dummy channel structure and an initial first stack of layers comprises the first layer in a staircase region. In some examples, the stack of layers corresponds to an initial second stack of layers, the method includes forming the initial second stack of layers that comprises insulating layers and sacrificial gate layers stacked alternatingly over the initial first stack of layers, and forming stair steps based on the initial second stack of layers in the staircase region. Further, the method includes planarizing the staircase region using an insulating material. Then, the method includes forming a dummy channel hole in the insulating material and the initial second stack of layers. An end of the dummy channel hole is in the first layer. Then the method includes forming the dummy channel structure in the dummy channel hole.

According to another aspect of the disclosure, the vertical structure corresponds to a gate line slit structure and an initial first stack of layers includes the first layer in a gate line slit region. The stack of layers corresponds to an initial second stack of layers, the method further includes forming the initial second stack of layers that comprises insulating layers and sacrificial gate layers stacked alternatingly over the initial first stack of layers. Then, the method includes forming channel structures in the initial second stack of layers, forming a trench in the initial second stack of layers with an end in the first layer, replacing, via the trench, the sacrificial gate layers with gate layers, and forming the gate line slit structure in the trench.

According to another aspect of the disclosure, the method includes forming a punch through contact structure in a punch through region by processing on the first side of the first die. In some examples, the method includes forming bonding structures on the first side of the first die, and bonding the first side with a second die before the processing on the second side of the first die. In an example, the method includes forming a through silicon contact by the processing on the second side of the first die. The through silicon contact conductively connects the punch through contact structure with a pad structure on the second side of the first die.

Aspects of the disclosure provide a layout design to use in the methods for semiconductor device fabrication.

Aspects of the disclosure provide semiconductor device and memory device systems that are fabricated according to in the methods for semiconductor device fabrication.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B show cross-sectional views of a semiconductor device 100 according to some embodiments of the disclosure.

FIGS. 2A-2C show layouts of patterns for defining a stop layer.

FIG. 3 shows a flow chart outlining a process 300 in some examples.

FIGS. 4A-4P show cross-sectional views of an array die in a semiconductor device, at various intermediate steps of wafer level manufacturing, in accordance with some embodiments.

FIG. 5 shows a block diagram of a memory system device according to some examples of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some aspects of the disclosure, vertical device technologies form vertical structures, such as channel structures, dummy channel structures, gate line slit structures in three dimensional (3D) NAND flash memory, and the like, on wafers. In some examples, the vertical structures can be formed in openings, such as holes or trenches that are etched into layers on a first side, also referred to as a front side, of a wafer. The etching process to form the holes or trenches can affect a depth uniformity of the holes. With the height increase of the vertical structures (e.g., to increase the number of memory cells in a vertical memory cell string), the depth of the holes or trenches is difficult to control and the depth uniformity of the holes or trenches can be poor. When the depth uniformity of the holes or trenches is poor, the ends of the vertical structures have poor depth uniformity and may cause significant variations in device electronic properties. Some semiconductor technologies form structures on both sides of the wafer using front side processing and backside processing. The poor depth uniformity of the ends of the vertical structures can cause difficulty in the backside processing.

Some aspects of the present disclosure provide techniques to improve depth control and depth uniformity of the ends of the vertical structures, and thus can increase process margins and ease the backside processing.

According to some aspects of the disclosure, a stop layer can be formed under a stack of layers in a region to form vertical structures. The vertical structures can be formed by etching holes or trenches into the stack of layers, and filling the holes or trenches with materials for the vertical structures. The etching of the holes or the trenches can stop in the stop layer. The etching properties of the stop layer can be used to control the depth of the ends of the vertical structures. In some examples that use backside processing, the stop layer can be removed by the backside processing, and can be replaced by another layer that is functional layer but may have inferior etching property to the stop layer.

For example, in the three dimensional (3D) NAND flash memory technology, channel structures are formed in a stack of layers with ends of the channel structures in a semiconductor layer. The semiconductor layer can be used for forming an array common source in some examples. However, etching properties of the semiconductor layer may cause poor depth control and poor depth uniformity during the etching process to form holes in the stack of layers for the channel structures. In some examples, a stop layer that has better etching properties than the semiconductor layer, such as better etching selectivity to the stack of layers than the semiconductor layer, can be formed under the stack of layers. In an example, the semiconductor layer is a polysilicon layer, and the stop layer includes Tungsten. It is noted that other suitable material that has better etching selectivity to the stack of layers than the polysilicon layer can be used in the stop layer. The holes can be etched through the stack of layers and ended in the stop layer with better depth control and better depth uniformity. After the formation of the channel structures, the stop layer can be replaced by a semiconductor layer using backside processing.

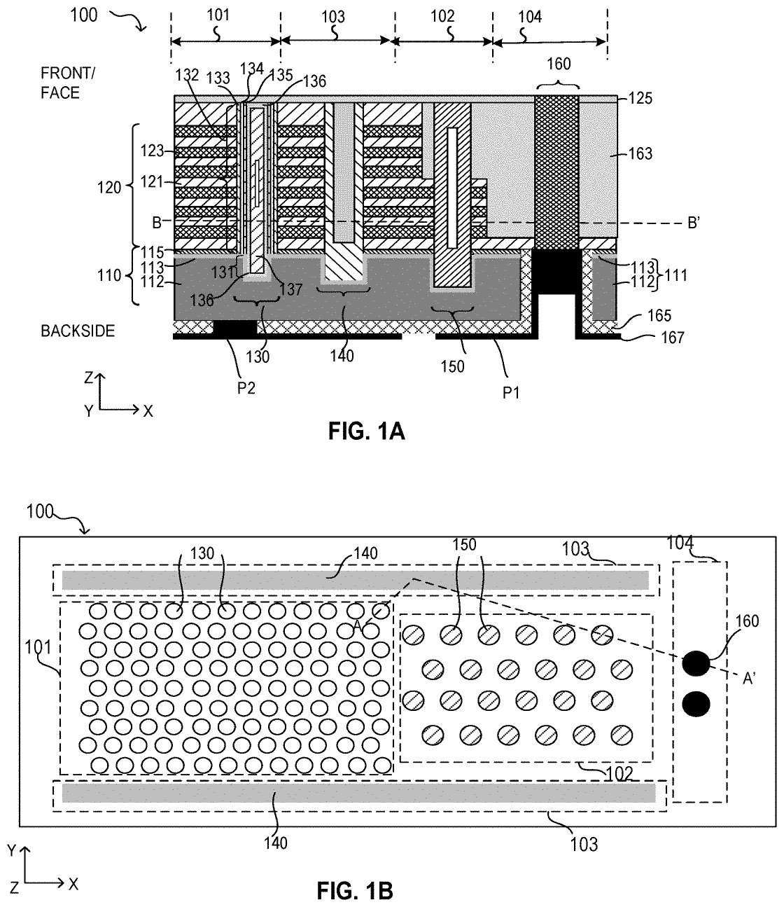

FIGS. 1A-1B show cross-sectional views of a semiconductor device 100 according to some embodiments of the disclosure. FIG. 1A shows the cross-sectional view along A′A line of the semiconductor device 100 shown in FIG. 1B and FIG. 1B shows the cross-sectional view along B′B line of the semiconductor device 100 shown in FIG. 1A. It is noted that for ease of illustration, features are not drawn to scale.

As shown in FIGS. 1A-1B, the semiconductor device 100 includes multiple regions and vertical structures formed in the multiple regions. Specifically, the semiconductor device 100 includes a core region 101, and channel structures 130 formed in the core region 101; the semiconductor device 100 includes a staircase region 102, and dummy channel structures 150 formed in the staircase region 102; the semiconductor device 100 includes a gate line slit region 103, and gate line slit structures 140 formed in the gate line slit region 103.

According to some aspects of the disclosure, at least a type of the vertical structures can be formed by utilizing a stop layer to achieve depth control and better depth uniformity in the vertical structures, and then the stop layer is replaced by a functional layer. In an example, a stop layer is formed in the core region 101 to achieve depth control and better depth uniformity in the channel structures 130. In another example, a stop layer is formed in the staircase region 102 to achieve depth control and better depth uniformity in the dummy channel structures 150. In another example, a stop layer is formed in the gate line slit region 103 to achieve depth control and better depth uniformity in the gate line slit structures 140.

In some examples, the stop layer is formed in multiple regions, to achieve depth control and better depth uniformity in multiple types of vertical structures. In an example, the stop layer is formed in the core region 101, the staircase region 102, and the gate line slit region 103 to achieve depth control and better depth uniformity respectively for the channel structures 130, the dummy channel structures 150, and the gate line slit structures 140. It is noted while the following description illustrates techniques of depth control and uniformity control using the example of utilizing the stop layer in the core region 101, the staircase region 102, the gate line slit region 103, the illustrated techniques can be suitably adjusted for use in other examples.

It is noted that while FIG. 1A shows that the semiconductor device 100 includes one die, the semiconductor device 100 can include additional die(s) that are not shown. In some examples, the semiconductor device 100 includes a first die shown in FIG. 1A and a second die (not shown) that are bonded face to face (e.g., front side to front side). For example, the first die (shown in FIG. 1A and FIG. 1B) includes a memory cell array formed on the front side and can be referred to as an array die; and the second die (not shown) includes periphery circuitry formed on the front side and can be referred to as periphery die. In some examples, the periphery circuitry is formed using complementary metal-oxide-semiconductor (CMOS) technology, and the periphery die is also referred to as CMOS die.

It is noted that, in some other embodiments, a semiconductor device can include multiple array dies and a CMOS die. The multiple array dies and the CMOS die can be stacked and bonded together. The CMOS die is respectively coupled to the multiple array dies, and can drive the respective array dies.

The semiconductor device 100 can be device at any suitable scale, such as wafer scale, chip scale, package scale and the like. In some examples (e.g., wafer scale), the semiconductor device 100 includes at least a first wafer and a second wafer bonded face to face. The array die is disposed with other array dies on the first wafer, and the CMOS die is disposed with other CMOS dies on the second wafer. The first wafer and the second wafer are bonded together, thus the array dies on the first wafer are bonded with corresponding CMOS dies on the second wafer. In some examples (e.g., chip scale), the semiconductor device 100 is a chip with at least the array die and the CMOS die bonded together. In an example, the chip is diced from wafers that are bonded together. In another example (e.g., package scale), the semiconductor device 100 is a semiconductor package that includes one or more semiconductor chips assembled on a package substrate.

FIG. 1A shows a channel structure 130 in the core region 101, a gate line slit structure 140 in the gate line slit region 103, a dummy channel structure 150 in the staircase region 102 and a punch through contact structure 160 in a punch through region 104.

The channel structure 130 includes a body portion 132 formed in a second stack 120 of layers, and an end portion 131 in a first stack 110 of layers. The first stack 110 of layers includes a semiconductor layer 111 that is form by replacing a stop layer (not shown) using backside processing. The second stack 120 of layers includes gate layers 123 and insulating layers 121 alternatingly stacked on a front side of the array die. The front side is opposite to the backside.

In some embodiments, the channel structure 130 has a pillar shape that extends in the Z direction that is perpendicular to the direction of the main surface X-Y plane. In an embodiment, the channel structure 130 is formed by materials in the circular shape (or elliptical shape or polygonal shape) in the X-Y plane, and extends in the Z direction. For example, the channel structure 130 includes function layers, such as a blocking insulating layer 133 (e.g., silicon oxide), a charge storage layer 134 (e.g., silicon nitride), a tunneling insulating layer 135 (e.g., silicon oxide), a semiconductor layer 136, and an insulating layer 137 that have the circular shape (or elliptical shape or polygonal shape)in the X-Y plane, and extend in the Z direction. In an example, the blocking insulating layer 133 (e.g., silicon oxide) is formed on the sidewall of a channel hole for the channel structure 130, and then the charge storage layer 134 (e.g., silicon nitride), the tunneling insulating layer 135, the semiconductor layer 136, and the insulating layer 137 are sequentially stacked from the sidewall. The semiconductor layer 136 can be any suitable semiconductor material, such as polysilicon or monocrystalline silicon, and the semiconductor material may be un-doped or may include a p-type or n-type dopant. In some examples, the semiconductor material is intrinsic silicon material that is un-doped. However due to defects, intrinsic silicon material can have a carrier density in the order of 10¹⁰ cm⁻³ in some examples. The insulating layer 137 is formed of an insulating material, such as silicon oxide and/or silicon nitride, and/or may be formed as an air gap.

According to some aspects of the disclosure, the channel structure 130 and the second stack 120 of layers together form a vertical memory cell string. For example, the semiconductor layer 136 corresponds to the channel portions for transistors in the memory cell string, and the gate layers 123 corresponds to the gates of the transistors in the vertical memory cells string. Generally, a transistor has a gate that controls a channel, and has a drain and a source at each side of the channel. For simplicity, in the FIG. 1A example, the upper side of the channel for transistors in FIG. 1A is referred to as the drain, and the bottom side of the channel for transistors in FIG. 1A is referred to as the source. It is noted that the drain and the source can be switched under certain driving configurations. In the FIG. 1A example, the semiconductor layer 136 corresponds to connected channels of the transistors. For a specific transistor, the drain of the specific transistor is connected with a source of an upper transistor above the specific transistor, and the source of the specific transistor is connected with a drain of a lower transistor below the specific transistor. Thus, the transistors in the vertical memory cell string are connected in series.

In the FIG. 1A example, the end portion 131 includes the semiconductor layer 136, and the insulating layer 137. In some examples, the blocking insulating layer 133, the charge storage layer 134, and the tunneling insulating layer 135 at the end portion 131 are removed by backside processing. In some examples, an initial end portion corresponding to the end portion 131 also includes the blocking insulating layer 133, the charge storage layer 134, and the tunneling insulating layer 135. The initial end portion is formed in an initial first stack of layer having a stop layer (not shown) in the core region 101. The stop layer can be removed by backside processing. The blocking insulating layer 133, the charge storage layer 134, and the tunneling insulating layer 135 at the initial end portion can be removed by the backside processing. Further, the semiconductor layer 111 can be formed by the backside processing.

According to some aspects of the disclosure, the semiconductor layer 136 at the end portion 131 corresponds to a source terminal of the vertical memory cell string, and the semiconductor layer 111 in the first stack 110 is configured to connect the source terminals of an array of the vertical memory cell strings to an array common source (ACS) terminal, such as shown by P2. In the FIG. 1A example, the semiconductor layer 111 includes a bulk portion 112 and a liner portion 113 (e.g. a conformal portion). The liner portion 113 is in contact with the semiconductor layer 136. In an example, the liner portion 113 can be doped by ion implantation to achieve a desired doping profile. In another example, the semiconductor layer 111 only includes the bulk portion 112 which is in contact with the semiconductor layer 136. In some examples, the semiconductor layer 111 is silicon material, such as doped polysilicon (such as N-type doped silicon, P-type doped silicon) and the like.

In the FIGS. 1A-1B example, the gate line slit (GLS) structure 140 is formed in the second stack 120 of layers with an end portion in the first stack 110 of layers. The GLS structures 140 can be used to facilitate replacement of sacrificial layers with the gate layers 123 in a gate-last process. In some examples, the GLS structure 140 is formed by filling a trench with one or more dielectric materials. In some examples, the GLS structure 140 extends through the second stack 120 of layers, the GLS structure 140 can divide the vertical memory cell strings (corresponding to the channel structures 130) into separate blocks. In some examples, the vertical memory cell strings are configured to be erased by block. Further, the quantity and arrangement of the channel structures 130 between the GLS structures 140 can vary.

The end portion of the GLS structure 140 is in the first stack 110 of layers. In some examples, the end portion of the GLS structure 140 is formed in an initial first stack of layer having a stop layer (not shown) in the gate line slit region 103. The stop layer can be removed by backside processing. Further, the semiconductor layer 111 can be formed by backside processing.

It is noted that in some examples (not shown), a GLS structure 140 may include a conductive material (not shown) and can be configured to function as an ACS terminal.

In the FIG. 1A example, the gate layers 123 and the insulating layers 121 are arranged in a form of stair steps in the staircase region 102. For example, each stair step can include one or more pairs of the insulating layer 121 and the gate layer 123. The staircase region 102 is also filled with insulating material 163 and is planarized with other regions. Gate contact structures (not shown) can be disposed on the stair steps and be connected to the respective gate layers 123. The gate contact structures are used to connect driving circuitry to the respective gate layers 123 to control the stacked memory cells and select gates.

In the FIGS. 1A-1B example, the dummy channel structures 150 are formed in staircase region 102 with an end portion in the first stack 110. The dummy channel structures 150 can prevent the second stack 120 of layers from collapsing during a replacement of sacrificial layers with the gate layers 123 in a gate-last process. The dummy channel structures 150 can include one or more dielectric materials. In an example, dummy channel structures 150 can be disposed in the staircase region 102 between the GLS structures 140. In another example, one or more dummy channel structures 150 can also be disposed in the core region 101.

The end portion of the dummy channel structure 150 is in the first stack 110 of layers. In some examples, the end portion of the dummy channel structure 150 is formed in an initial first stack of layers having a stop layer (not shown) in the staircase region 102. The stop layer can be removed by backside processing. Further, the semiconductor layer 111 can be formed by backside processing.

In the FIGS. 1A-1B example, punch through contact structure 160 is formed in the punch through region 104. In the FIG. 1A example, the punch through region 104 is filled with the insulating material 163 and is planarized with other regions. The punch through contact structure 160 can extend from the front side of the array die to the backside of the array die, and conductively interconnect conductive structures on the front side of the array die with conductive structures on the backside of the array die.

In an example, the punch through contact structure 160 extends through a capping layer 125, the insulating layer 163 and stops in a top etch stop layer 115. In some examples, the end of the punch through contact structure 160 can be in contact with a conductive layer 167, and is conductively connected to a pad structure P2. The conductive layer 167 can include one or more metal materials, such as aluminum (Al), titanium (Ti), and the like. The conductive layer 167 can be separated from the semiconductor layer 111 by a spacer layer 165, such as silicon oxide.

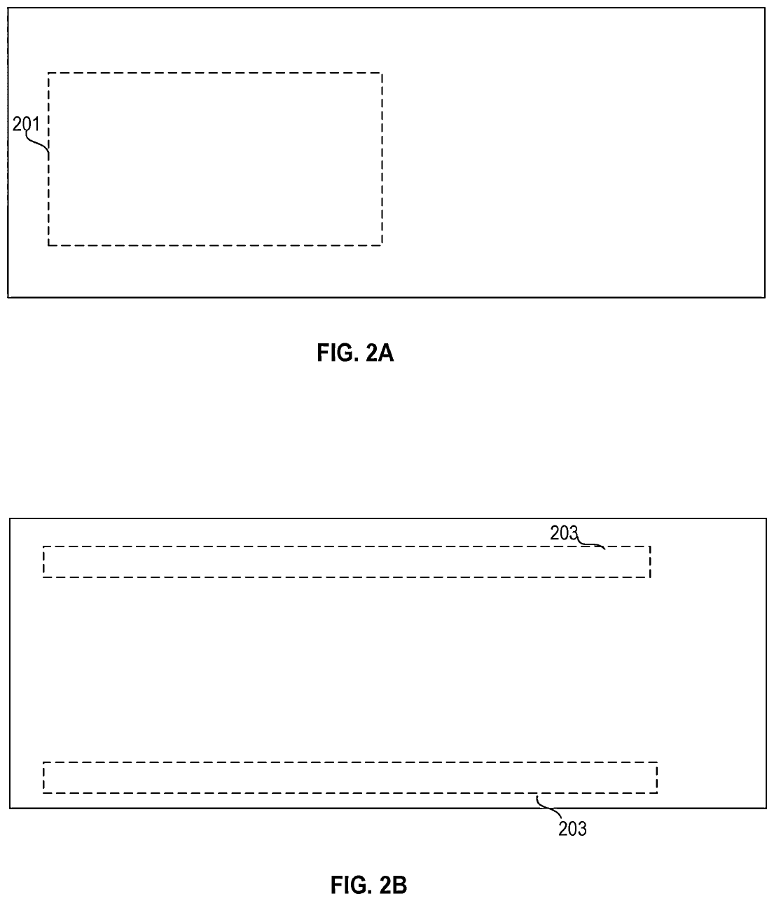

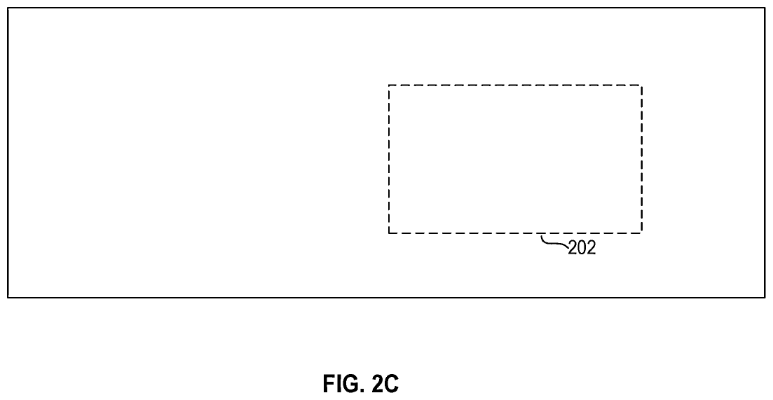

FIGS. 2A-2C show layouts of patterns for defining a stop layer. FIG. 2A shows a pattern 201 that can be used to form the stop layer in the core region 101 to achieve depth control and better depth uniformity of the channel structures 130.

FIG. 2B shows patterns 203 that can be used to form the stop layer in the gate line slit region 103 to achieve depth control and better depth uniformity of the gate line slit structures 140.

FIG. 2C shows a pattern 202 that can be used to form the stop layer in the staircase region 102 to achieve depth control and better depth uniformity of the dummy channel structures 150.

In some examples, the stop layer is not patterned, no additional layout or mask is needed.

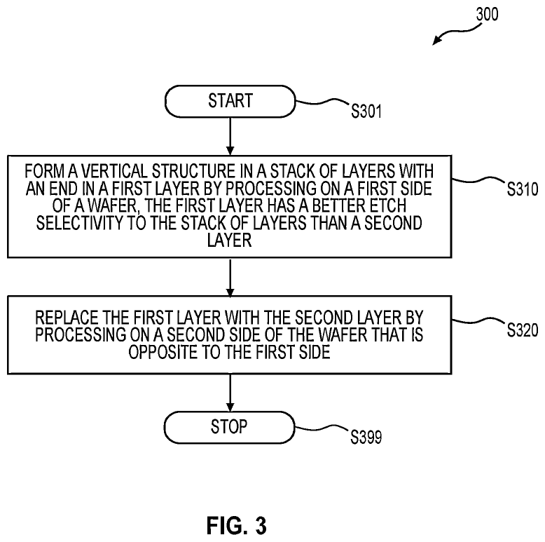

FIG. 3 shows a flow chart outlining a process 300 in some examples. The process 300 can be used to form a semiconductor device, such as the semiconductor device 100, and the like. The process starts at S301 and proceeds to S310.

At S310, a vertical structure is formed in a stack of layers by processing on a first side of a wafer. The end of the vertical structure is in a first layer that has a better etch selectivity to the stack of layers than a second layer.

In the example in FIGS. 1A-1B, an initial first stack of layers corresponding to the first stack 110 can include a stop layer that has a better etch selectivity to layers above the initial first stack of layers than a polysilicon layer. In an example, the stop layer includes tungsten (W). In the FIGS. 1A-1B example, in the core region 101, layers above the initial first stack of layers can include silicon oxide layers and silicon nitride layers that are stacked alternatingly, the tungsten has a better etch selectivity to the layers above the initial first stack than polysilicon layer. Channel holes for the channel structures 130 are etched through the layers above the initial first stack and stopped in the stop layer. The channel structures 130 are formed in the channel holes with the ends in the stop layer within the core region 101.

In the staircase region 102, layers above the initial first stack of layers can include a subset of the silicon oxide layers and silicon nitride layers that are stacked alternatingly and additional insulating material 163, the tungsten has a better etch selectivity to the layers above the initial first stack than the polysilicon layer. Dummy channel holes for the dummy channel structures 150 are etched through the layers above the initial first stack and stopped in the stop layer. The dummy channel structures 150 are formed in the dummy channel holes with the ends in the stop layer within the staircase region 102.

In the gate line slit region 103, layers above the initial first stack of layers can include the silicon oxide layers and the silicon nitride layers that are stacked alternatingly, the tungsten has a better etch selectivity to the layers above the initial first stack than polysilicon layer. Trenches for the gate line slit structures 140 are etched through the layers above the initial first stack and stopped in the stop layer. The gate line slit structures 140 are formed in the trenches with the ends in the stop layer.

At S320, the first layer is replaced by the second layer by processing on a second side of the wafer that is opposite to the first side. In the example of FIGS. 1A-1B, backside processing is performed to remove some layers from the backside of the wafer, such as a substrate, an oxide layer, the stop layer, the blocking insulating layer 133 at the end of the channel structures 130, the charge storage layer 134 at the end of the channel structures 130, and the tunneling insulating layer 135 at the end of the channel structures 130. Then, the semiconductor layer 111, such as a polysilicon layer can be formed at the backside of the wafer. In some examples, through silicon contact structure can be formed to be conductively connected with the punch through contact structures 160.

The process can continue until the finish of the manufacturing process.

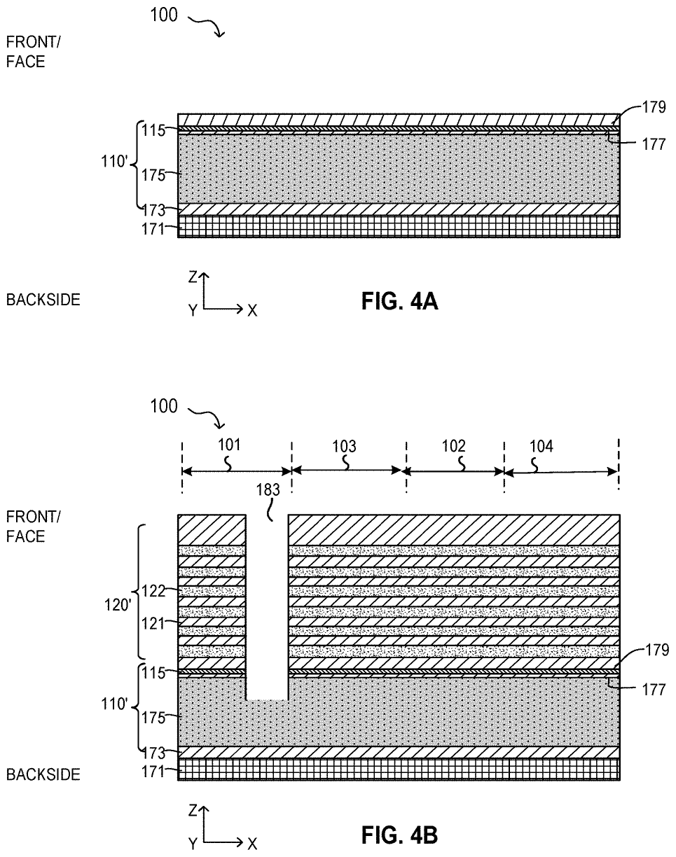

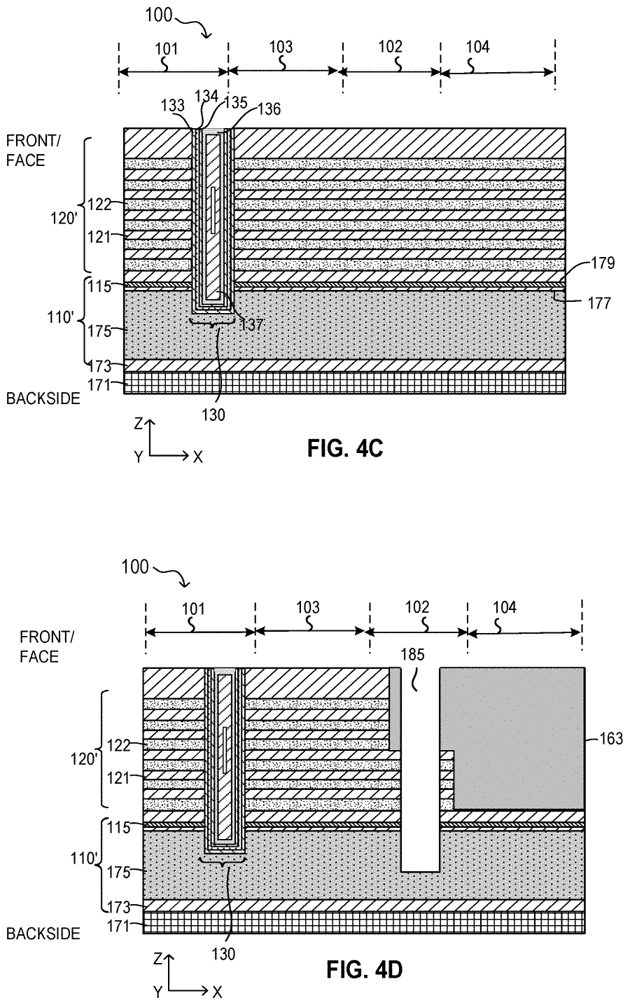

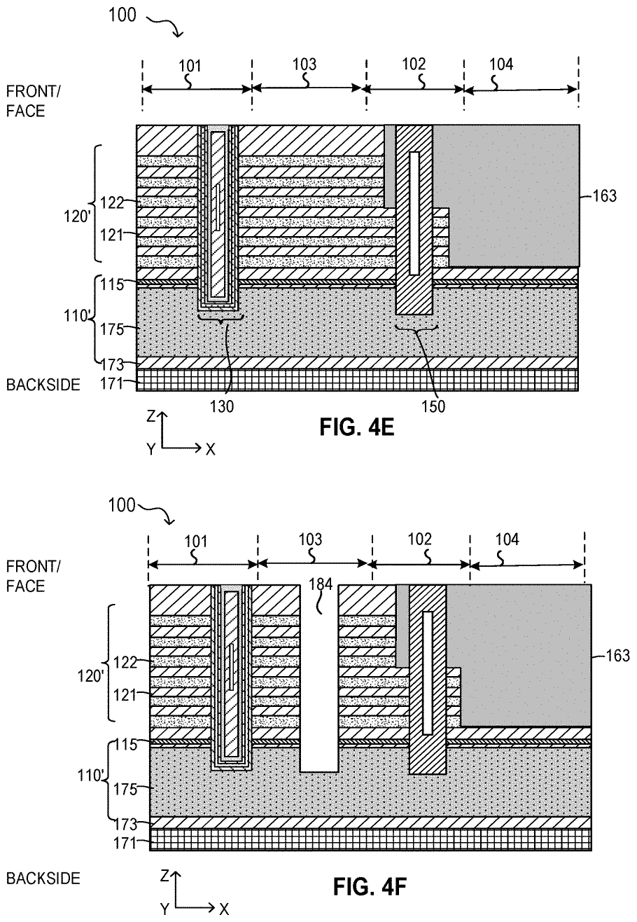

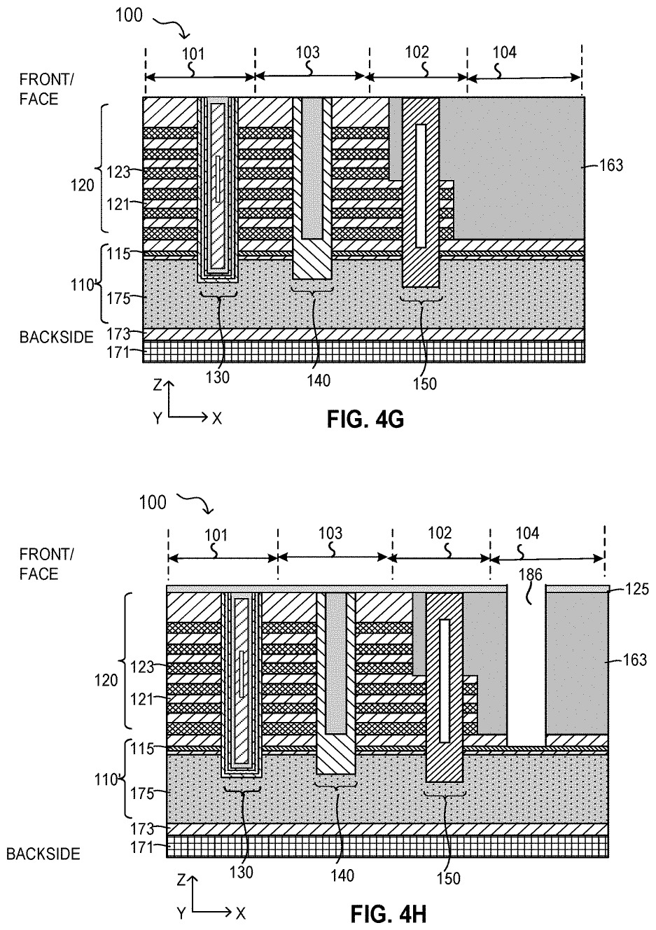

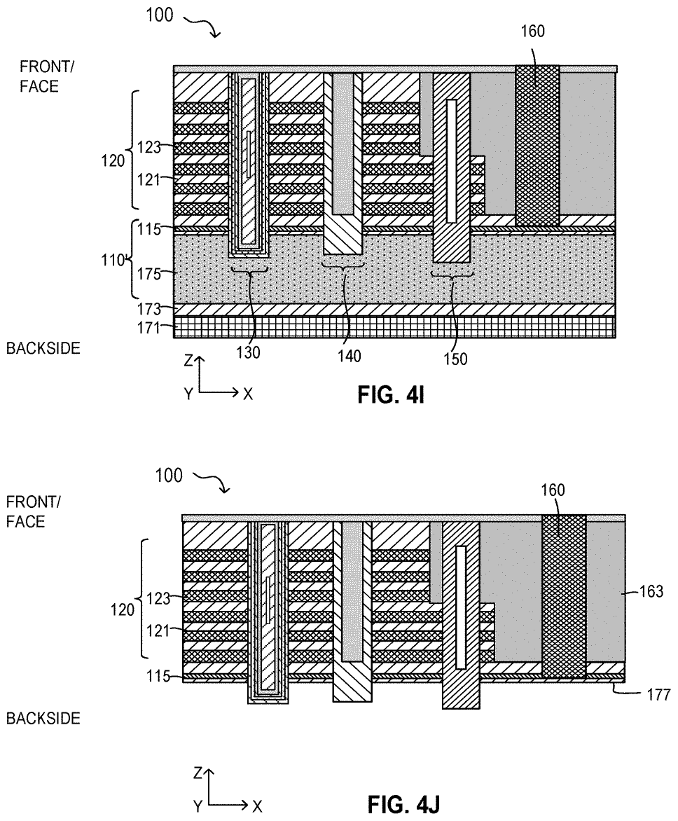

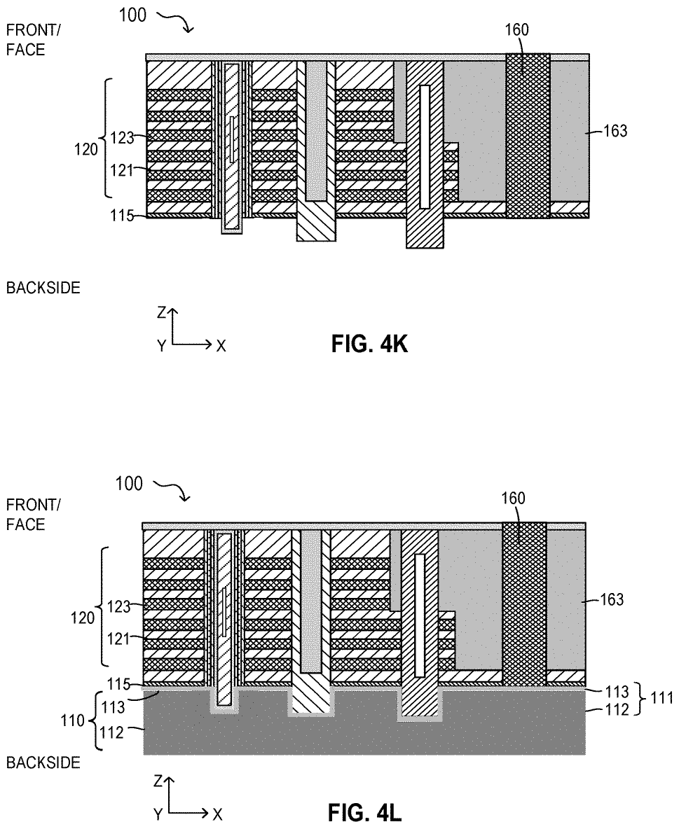

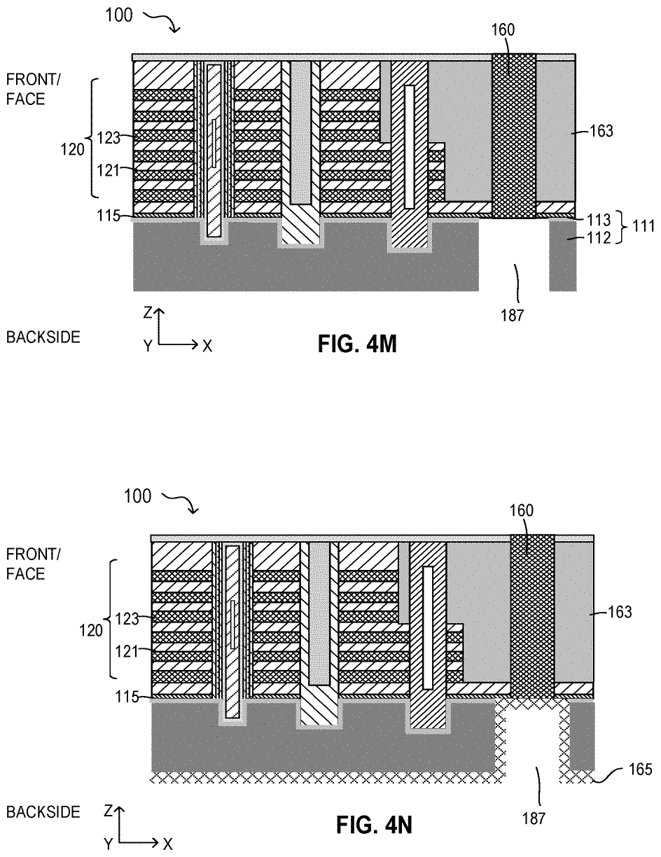

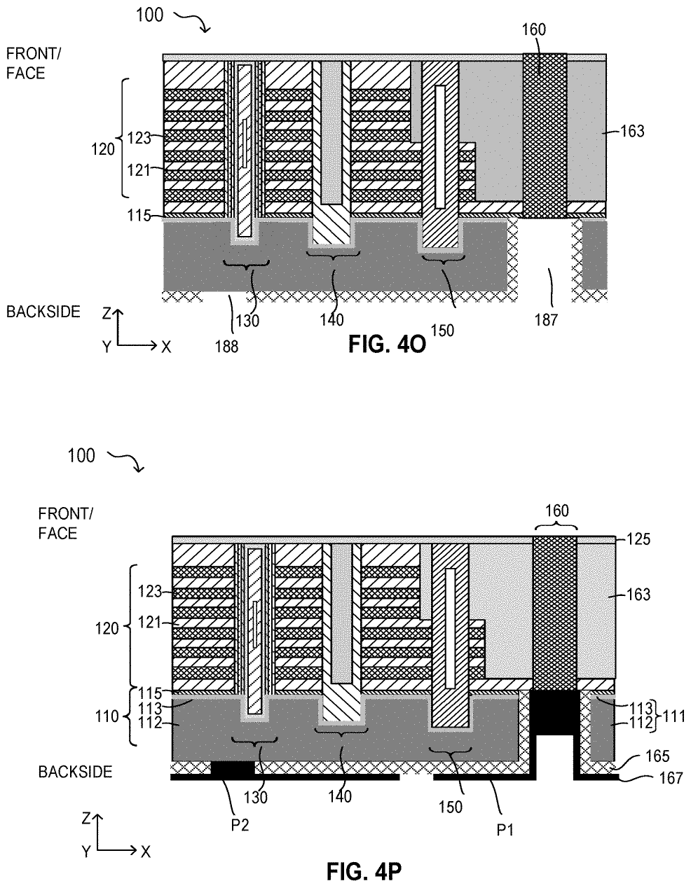

FIGS. 4A-4P are cross-sectional views of an array die in a semiconductor device, such as the array die in the semiconductor device 100, at various intermediate steps of wafer level manufacturing, in accordance with some embodiments of the present disclosure.

FIG. 4A shows a cross-sectional view of the semiconductor device 100 after a deposition of an initial first stack 110′ of layers on a substrate 171. In the FIG. 4A example, the initial first stack 110′ includes a first oxide layer 173, a stop layer 175, a second oxide layer 177, a top etch stop layer 115, and a third oxide layer 179 that are sequentially deposited on the substrate 171. In an example, the stop layer 175 includes tungsten, and has a thickness to ensure the etching of channel holes for forming channel structures, the etching of dummy channel holes for forming the dummy channel structure, and the etching of trenches for forming gate line slit structures, can stop in the stop layer 175.

FIG. 4B shows a cross-sectional view of the semiconductor device 100 after channel holes 183 for forming channel structures are etched through an initial second stack 120′ of layers. The etching of the channel holes 183 stops in the stop layer 175. For example, the initial second stack 120′ of layers is formed over the initial first stack 110′ of layers. The initial second stack 120′ of layers can include insulating layers 121 (e.g., silicon oxide) and sacrificial gate layers 122 (e.g., silicon nitride) which are stacked alternatingly in the Z direction. Then, photo lithography technology is used to define patterns of channel holes in photoresist and/or hard mask layers, and etch technology is used to transfer the patterns into the initial second stack 120′ of layers and the initial first stack 110′ of layers, and the etch stops in the stop layer 175. The stop layer 175 has a relatively large etch selectivity to the insulating layers 121 and the sacrificial gate layer 122, and a depth of the channel holes 183 in the stop layer 175 can be well controlled, and the channel holes 183 can have relatively uniform depth.

FIG. 4C shows a cross-sectional view of the semiconductor device 100 after channel structures 130 are formed. In an example, the blocking insulating layer 133 (e.g., silicon dioxide) is formed on the sidewall of channel holes, and then the charge storage layer 134 (e.g., silicon nitride), the tunneling insulating layer 135, the semiconductor layer 136, and the insulating layer 137 are sequentially stacked from the sidewall.

It is noted that the channel structures 130 is not limited to a single deck form as shown in FIG. 4C. In some examples (not shown), the channel structures 130 are formed using multi-deck technology. For example, a channel structure 130 include a lower channel structure in a lower deck and an upper channel structure in an upper deck. The lower channel structure and the upper channel structurer are suitably joined to form the channel structure 130.

FIG. 4D shows a cross-sectional view of the semiconductor device 100 after dummy channel holes 185 for forming dummy channel structures are etched through layers in the staircase region. In some examples, stair steps are suitable formed in the staircase region, and the insulating material 163 (e.g., silicon oxide) is filled and suitably planarized. Then, photo lithography technology is used to define patterns of dummy channel holes in photoresist and/or hard mask layers, and etch technology is used to transfer the patterns into layers in the staircase region, and the etch stops in the stop layer 175. The stop layer 175 has a relatively large etch selectivity to the insulating material 163, the insulating layers 121 and the sacrificial gate layer 122, and a depth of the dummy channel holes in the stop layer 175 can be well controlled, and the dummy channel holes can have relatively uniform depth.

FIG. 4E shows a cross-sectional view of the semiconductor device 100 after dummy channel structures 150 are formed. In some examples, one or more insulating layers are formed in the dummy channel holes. In an example, one or more insulating layers are deposited and excess insulating materials at areas out of the dummy channel holes can be removed for example by chemical mechanical polishing (CMP) and or etch process.

FIG. 4F shows a cross-sectional view of the semiconductor device 100 after trenches 184 for forming the gate line slit structures are etched through layers in the gate line slit region. The trenches 184 are also referred to as gate line slits or gate line cuts. In some examples, photo lithography technology is used to define patterns of the trenches in photoresist and/or hard mask layers, and etch technology is used to transfer the patterns into the initial second stack 120′ of layers and the initial first stack 110′ of layers, and the etch stops in the stop layer 175. The stop layer 175 has a relatively large etch selectivity to the insulating layers 121 and the sacrificial gate layer 122, and a depth of the trenches in the stop layer 175 can be well controlled, and the trenches can have relatively uniform depth.

FIG. 4G shows a cross-sectional view of the semiconductor device 100 after the gate line slit structures 140 are formed in the gate line slit region 103.

In some examples, using the trenches, the sacrificial gate layers 122 can be replaced by the gate layers 123. In an example, etchants to the sacrificial gate layers 122 are applied via the trench to remove the sacrificially gate layers. In an example, the sacrificial gate layers are made of silicon nitride, and the hot sulfuric acid (H₂SO₄) is applied via the trenches to remove the sacrificial gate layers. Further, via the trenches, gate stacks to the transistors in the array region are formed. In an example, a gate stack is formed of a high-k dielectric layer, a glue layer and a metal layer. The high-k dielectric layer can include any suitable material that provide the relatively large dielectric constant, such as hafnium oxide (HfO₂), hafnium silicon dioxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon dioxide (ZrSiO₄), hafnium zirconium oxide (HfZrO₄), and the like. The glue layer can include refractory metals, such as titanium (Ti), tantalum (Ta) and their nitrides, such as TiN, TaN, W2N, TiSiN, TaSiN, and the like. The metal layer includes a metal having high conductivity, such as tungsten (W), copper (Cu) and the like.

Further, the trenches can be filled to form the gate line slit structures 140. In some examples, one or more insulating layers are formed in the trenches. In an example, one or more insulating layers are deposited and excess insulating material at areas out of the trenches can be removed for example by CMP and/or etch process. In some examples, conductive material, such as tungsten, can be used to form array common source terminal in the gate line slit structures 140.

FIG. 4H shows a cross-sectional view of the semiconductor device 100 after the punch through holes 186 for forming the punch through contact structures are etched through layers in the punch through region. For example, the capping layer 125 is deposited and planarized. Further, photo lithography technology is used to define patterns of the punch through holes in photoresist and/or hard mask layers, and etch technology is used to transfer the patterns into the capping layer 125 and the insulating material 163, and the etch can stop in the top etch stop layer 115. It is noted that the etch can stop in other suitable layer. In some examples, the punch through holes 186 are formed with other contact holes (not shown), such as word line contact holes, bit line contact holes and the like by the same process steps and at the same time.

FIG. 4I shows a cross-sectional view of the semiconductor device 100 after the punch through contact structures 160 are formed in the punch through holes. For example, suitable liner layer (e.g., titanium/titanium nitride) and a metal layer (e.g., tungsten) can be filled into the punch through holes to form the punch through contact structures. In some examples, the punch through contact structures are formed with other contact structures, such as word line contact structures (also referred to as gate contact structures in some examples), bit line contact structures and the like by the same process steps and at the same time.

In some embodiments, bonding structures (not shown) are then formed on the front side of the array die. Further, the array die is bonded with a CMOS die (not shown) face to face. Then, backside processing can be performed on the array die.

FIG. 4J shows a cross-sectional view of the semiconductor device 100 after the stop layer 175 is removed by the backside processing. In some examples, the substrate 171 is removed by the backside processing, such as applying CMP process, and/or etch process on the backside of the array die. Then, the oxide layer 173 is removed by backside processing, such as applying CMP process, and/or etch process on the backside of the array die. Then, the stop layer 175 is removed by the backside processing, such as applying CMP process, and/or etch process on the backside of the array die.

As a result, the ends of the channel structures 130, the ends of the gate line slit structures 140 and the ends of the dummy channel structures 150 can be exposed from the backside of the array die.

FIG. 4K shows a cross-sectional view of the semiconductor device 100 after the blocking insulating layer, the charge storage layer, and the tunneling insulating layer, are removed from the ends of the channel structures 130 by the backside processing. It is noted that the second oxide layer 177 is also removed by the back side processing.

FIG. 4L shows a cross-sectional view of the semiconductor device 100 after the semiconductor layer 111 is formed by the backside processing. In some examples, the semiconductor layer 111 includes a bulk portion 112 and a liner portion 113 (e.g. a conformal portion). The liner portion 113 can be formed by, for example, atomic layer deposition and doped by ion implantation. Then, the bulk portion 112 can be formed, for example by chemical vapor deposition (CVD), and planarized by CMP. The bulk portion 112 can be doped in situ during CVD or doped by ion implantation after CVD. A post-annealing step, such as laser annealing, may be executed to activate dopants and/or repair crystal damages. In some examples, the semiconductor layer 111 only includes the bulk portion 112.

FIG. 4M shows a cross-sectional view of the semiconductor device 100 after a through silicon hole 187 is formed in the semiconductor layer 111 to expose the end of the punch through contact structure 160 from the backside of the array die.

FIG. 4N shows a cross-sectional view of the semiconductor device 100 after a spacer layer 165 is formed from the backside of the array die.

FIG. 4O shows a cross-sectional view of the semiconductor device 100 after some portions of the spacer layer 165 are removed. For example, the spacer layer 165 is removed from a bottom of the through silicon hole 187 so that the punch through contact structure 160 is exposed. It is noted that a portion of the spacer layer 165 on the semiconductor layer 111 is removed to generate an opening 188.

FIG. 4P shows a cross-sectional view of the semiconductor device 100 after the conductive layer 167 is formed on the backside of the array die and patterned, for example into pad structures, such as shown by P1 and P2. In some examples, the conductive layer 167 includes aluminum.

It is noted that the semiconductor device 100 can be suitably used in a memory system.

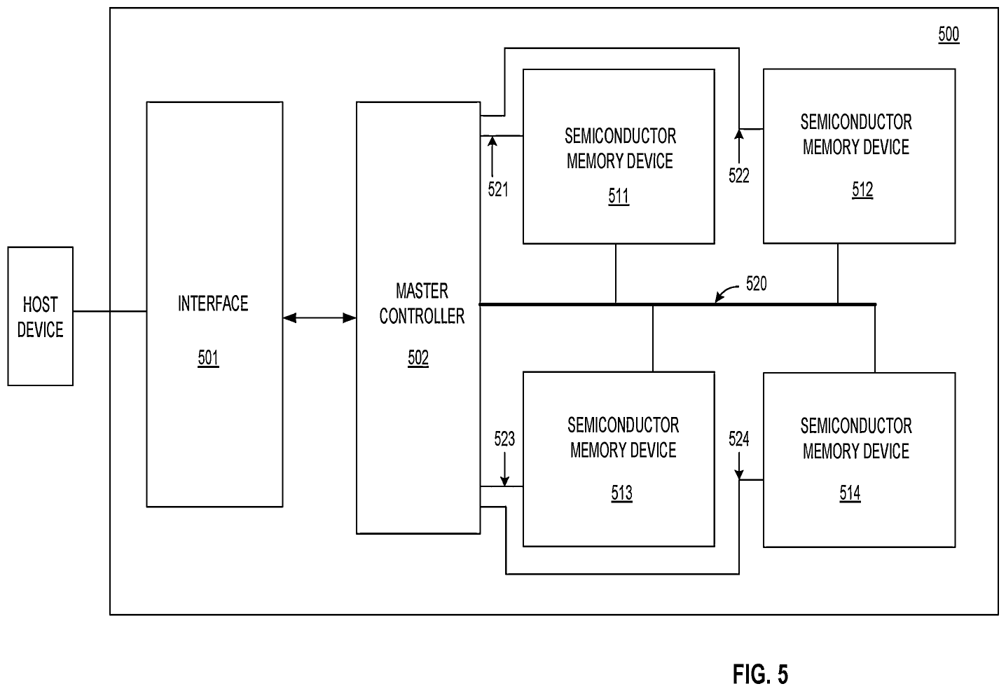

FIG. 5 shows a block diagram of a memory system device 500 according to some examples of the disclosure. The memory system device 500 includes one or more semiconductor memory devices, such as shown by semiconductor memory devices 511-514, that are respectively configured similarly as the semiconductor device 100. In some examples, the memory system device 500 is a solid state drive (SSD).

The memory system device 500 includes other suitable components. For example, the memory system device 500 includes an interface 501 and a master controller 502 coupled together as shown in FIG. 5. The memory system device 500 can include a bus 520 that couples the master controller 502 with the semiconductor memory devices 511-514. In addition, the master controller 502 is connected with the semiconductor memory devices 511-514 respectively, such as shown by respective control lines 521-524.

The interface 501 is suitably configured mechanically and electrically to connect between the memory system device 500 and a host device, and can be used to transfer data between the memory system device 500 and the host device.

The master controller 502 is configured to connect the respective semiconductor memory devices 511-514 to the interface 501 for data transfer. For example, the master controller 502 is configured to provide enable/disable signals respectively to the semiconductor memory devices 511-514 to active one or more semiconductor memory devices 511-514 for data transfer.

The master controller 502 is responsible for the completion of various instructions within the memory system device 500. For example, the master controller 502 can perform bad block management, error checking and correction, garbage collection, and the like.

The foregoing outlines features of several examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the examples introduced herein. Those skilled in the art should also realize that such equivalent constructions do not depart from the spirit and scope of the present disclosure, and that they may make various changes, substitutions, and alterations herein without departing from the spirit and scope of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for semiconductor device fabrication, comprising:
forming a vertical structure in a stack of layers with an end in a first layer by processing on a first side of a first die and
replacing the first layer with a second layer by processing on a second side of the first die that is opposite to the first side, a material of the first layer having a better etch selectivity to the stack of layers than a material of the second layer.

2. The method of claim 1, wherein the material of the first layer is tungsten and the material of the second layer is polysilicon.

3. The method of claim 1, wherein the vertical structure corresponds to a channel structure, and an initial first stack of layers comprises the first layer in a core region.

4. The method of claim 3, wherein the stack of layers corresponds to an initial second stack of layers, the method further comprises:
forming the initial second stack of layers that comprises insulating layers and sacrificial gate layers stacked alternatingly over the initial first stack of layers .

5. The method of claim 4, further comprising:
forming a channel hole in the initial second stack of layers with an end in the first layer; and
forming the channel structure in the channel hole.

6. The method of claim 5, wherein the channel structure comprises a channel layer that is wrapped in a blocking insulating layer, a charge storage layer, and a tunneling insulating layer.

7. The method of claim 6, wherein replacing the first layer with the second layer further comprising:
removing the first layer by the processing on the second side; and
removing the blocking insulating layer, the charge storage layer, and the tunneling insulating layer from an end of the channel structure by the processing on the second side.

8. The method of claim 7, wherein replacing the first layer with the second layer further comprises:
forming the second layer in contact with the channel layer at the end of the channel structure.

9. The method of claim 8, wherein replacing the first layer with the second layer further comprises:
forming a semiconductor layer in contact with the channel layer at the end of the channel structure by the processing on the second side.

10. The method of claim 9, wherein forming the semiconductor layer in contact with the channel layer further comprises:
forming a liner portion of the semiconductor layer, the liner portion contacting the channel layer at the end of the channel structure;
performing ion implantation to dope the liner portion; and
forming a bulk portion of the semiconductor layer.

11. The method of claim 9, further comprising:
forming a pad structure on the second side, the pad structure being conductively connected with the semiconductor layer.

12. The method of claim 1, wherein the vertical structure corresponds to a dummy channel structure and an initial first stack of layers comprises the first layer in a staircase region.

13. The method of claim 12, wherein the stack of layers corresponds to an initial second stack of layers, the method further comprises:
forming the initial second stack of layers that comprises insulating layers and sacrificial gate layers stacked alternatingly over the initial first stack of layers ;
forming stair steps based on the initial second stack of layers in the staircase region; and
planarizing the staircase region using an insulating material.

14. The method of claim 13, further comprising:
forming a dummy channel hole in the insulating material and the initial second stack of layers, an end of the dummy channel hole in the first layer; and
forming the dummy channel structure in the dummy channel hole.

15. The method of claim 1, wherein the vertical structure corresponds to a gate line slit structure and an initial first stack of layers comprises the first layer in a gate line slit region.

16. The method of claim 15, wherein the stack of layers corresponds to an initial second stack of layers, the method further comprises:
forming the initial second stack of layers that comprises insulating layers and sacrificial gate layers stacked alternatingly over the initial first stack of layers .

17. The method of claim 16, further comprising:
forming channel structures in the initial second stack of layers;
forming a trench in the initial second stack of layers with an end in the first layer;
replacing, via the trench, the sacrificial gate layers with gate layers; and
forming the gate line slit structure in the trench.

18. The method of claim 1, further comprising:
forming a punch through contact structure in a punch through region by processing on the first side of the first die.

19. The method of claim 18, further comprising:
forming bonding structures on the first side of the first die; and
bonding the first side with a second die before the processing on the second side of the first die.

20. The method of claim 19, further comprising:
forming a through silicon contact by the processing on the second side of the first die, the through silicon contact connecting the punch through contact structure with a pad structure on the second side of the first die.
